(19) United States
(12) Patent Application Publication
(10) Pub. No.: US 2003/0215994 A1
(43) Pub. Date: Nov. 20, 2003

(54) Method for forming ruthenium film of a semiconductor device

(76) Inventors: Jung-Hwan Choi, Sungbuk-gu (KR); Kyung-Woong Park, Songpa-gu (KR); Young-Ki Han, Gangbuk-gu (KR)

Correspondence Address: BAKER & DANIELS, 300 NORTH MERIDIAN STREET, SUITE 2700, INDIANAPOLIS, IN, 46204-1782, US

(21) Appl. No.: 10/374,304

(22) Filed: Feb. 25, 2003

(30) Foreign Application Priority Data
May 16, 2002 (KR) 2002-27096

(51) Int. Cl. H01L 21/44; H01L 21/8242; H01L 21/336

(52) U.S. Cl. 438/240; 438/286

(57) ABSTRACT

A method for forming ruthenium film of a semiconductor device comprises (a) forming a barrier layer on a semiconductor substrate; (b) loading the semiconductor substrate on which the barrier layer is formed into a reaction chamber; (c) supplying Ru(OD)₃ into the reaction chamber to be absorbed onto the barrier layer; (d) purging the reaction chamber by supplying argon gas into the reaction chamber; (e) supplying reaction gas containing oxygen into the reaction chamber and forming a ruthenium atomic layer by removing a ligand of RU(OD)₃ on the barrier layer using the oxygen gas; (f) purging the reaction chamber by supplying argon gas into the reaction chamber again; and (g) forming a ruthenium film having a certain thickness on the barrier layer by repeating steps from the step (c) and to the step (f) while the semiconductor substrate is kept at a temperature of 200˜350° C.

This application claims the benefit of Korean Patent Application No. 2002-27096, filed on May 16, 2002 in Korea, which is hereby incorporated by reference for all purposes as if fully set forth herein.

### BACKGROUND OF THE INVENTION

1. Field of the Invention

The present invention relates to a manufacturing method for a semiconductor device and more particularly, to a method for forming Ru (ruthenium) film of a semiconductor device that has improved qualities.

2. Discussion of the Related Art

A development for a new material has been actively performed in the field and diverse large-scale integrated circuit (LSI) such as ultra large-scale integrated circuit (ULSI) has been developed due to a rapid growth of the new material development. That is, because the new material for forming thin films such as an insulating layer, a semiconductor layer and a conductor layer, which constitute a semiconductor device, has been developed widely in the field, the large-scale integrated circuit (LSI) such as the ultra large-scale integrated (ULSI) circuit is available now. The semiconductor devices are generally fabricated by repeated depositing and patterning process. These processes are usually accomplished in a chamber type process module under vacuum condition.

It is desirable to use dielectric substances such as Ta₂O₅ and BST ((Ba,Sr)TiO₃) that has a high dielectric constant for a MIM (metal-insulator-metal) capacitor of the large-scale integrated circuit (LSI). However, if the dielectric substance such as Ta₂O₅ and BST ((Ba,Sr)TiO₃)are selected for the MIM capacitor, silicon is not a proper material for a capacitor electrode because of a contact resistance by an oxide and a low dielectric film that is naturally formed by oxygen. Accordingly, new metal materials for the capacitor electrode such as platinum (Pt), iridium (Ir) and ruthenium (Ru) have been actively researched in the field and the ruthenium (Ru) has been paid most attention for the capacitor electrode. Meanwhile, because a lower capacitor electrode has necessarily a cubic structure to increase a storage capacitance in the large-scale integrated circuit (LSI), it is difficult to deposit a material for an upper capacitor electrode by a typical sputtering method. Ruthenium (Ru) film is usually formed by a MOCVD (Metal-Organic Chemical Vapor Deposition) method. The MOCVD method is one of a LPCVD (Low-Pressure Chemical Vapor Deposition) methods. More specifically, a ruthenium (Ru) source material and oxygen (O₂) are supplied into a reaction chamber and then a pure ruthenium (Ru) film is deposited by removing a ligand that is included in the ruthenium (Ru) source material by the oxygen (O₂). A property of the deposited ruthenium (Ru) film greatly depends on a ratio of the oxygen (O₂) to the ruthenium source material. That is, as the oxygen (O₂) ratio increases, a step coverage is improved but a surface roughness of the deposited ruthenium film becomes worse and a specific resistance tends to increase. In addition, it is difficult for the ruthenium film to form a core in the beginning of deposition process and accordingly it takes a long time for an incubation time and the deposited film forms an island shape after the formation of the core. Accordingly, if the ruthenium film is deposited on TiN or BST material, a surface state of the deposited ruthenium film becomes very rough and a deposition rate is greatly decreased.

FIG. 1 is a scanning electron microscopic (SEM) photograph of a ruthenium film that is deposited on SiO₂ film according to the related art and FIG. 2 is a scanning electron microscopic (SEM) photograph of a ruthenium film that is deposited on TiN film according to the related art. As shown in FIG. 1 and FIG. 2, the surface roughness of the deposited ruthenium film is very rough. More specifically, the surface roughness of the ruthenium film that is deposited on SiO₂ film is about 20 Å in RMS (root mean square) value and the surface roughness of the ruthenium film that is deposited on TiN film is about 50 Å in RMS value. Required properties for the ruthenium as the capacitor electrode is to have a smooth surface and satisfactory step coverage as well as a low electric resistance when the ruthenium film is deposited on complex and minute patterns. However, the two conditions stated above cannot be satisfied at the same time according to the related art. That is, there is a limit in a range of the ruthenium film deposition owing to the ratio of the oxygen (O2) to the ruthenium source material and other process conditions. Moreover, because the surface roughness of the ruthenium film becomes very rough under the process condition for improving the step coverage as a line width of the semiconductor device becomes narrow, it is difficult to apply the ruthenium to an actual process for forming the capacitor electrode. As state above, because a growth of the ruthenium thin film greatly depends on a material on which the ruthenium film is formed according to the related art, the incubation time becomes very long and the surface of the deposited ruthenium film becomes very rough. Because of the problems above stated, if the ruthenium film that is formed according to the related art is used for the capacitor electrode having a high dielectric substance, the deposited ruthenium deteriorates an electric properties of the semiconductor device and thus cannot be actually applied to the process for forming capacitor electrode of the semiconductor device.

### SUMMARY OF THE INVENTION

Accordingly, the present invention is directed to a method for forming a ruthenium film of a semiconductor device that substantially obviates one or more of problems due to limitations and disadvantages of the related art.

An advantage of the present invention is to provide a method for forming a ruthenium film for a semiconductor device in which the ruthenium film is deposited by repeating a cycle that comprises a step of supplying source material into a reaction chamber, a step of purging the chamber by argon gas, a step of supplying oxygen containing gas and a step of purging the chamber by argon gas to improve a surface roughness, a specific resistance and a step coverage of the deposited ruthenium film.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a method for forming ruthenium film of a semiconductor device comprises (a) forming a barrier layer on a semiconductor substrate; (b) loading the semiconductor substrate on which the barrier layer is formed into a reaction chamber; (c) supplying Ru(OD)₃ into the reaction chamber to be absorbed onto the barrier layer; (d) purging the reaction chamber by supplying argon gas into the reaction chamber; (e) supplying reaction gas containing oxygen into the reaction chamber and forming a ruthenium atomic layer by removing a ligand of RU(OD)₃ on the barrier layer using the oxygen gas; (f) purging the reaction chamber by supplying argon gas into the reaction chamber again; and (g) forming a ruthenium film having a certain thickness on the barrier layer by repeating steps from the step (c) and to the step (f) while the semiconductor substrate is kept at a temperature of 200˜350° C. The barrier layer is formed one of SiO2 and TiN and the ruthenium film serves as a lower electrode of a capacitor for the semiconductor device. The barrier layer is formed one of high dielectric substance such as Ta₂O₅ and BST and the ruthenium film serves as an upper electrode of a capacitor for the semiconductor device. The reaction gas containing oxygen is one of oxygen gas and Na₂O.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a scanning electron microscopic (SEM) photograph of a ruthenium film that is deposited on SiO₂ film according to the related art;

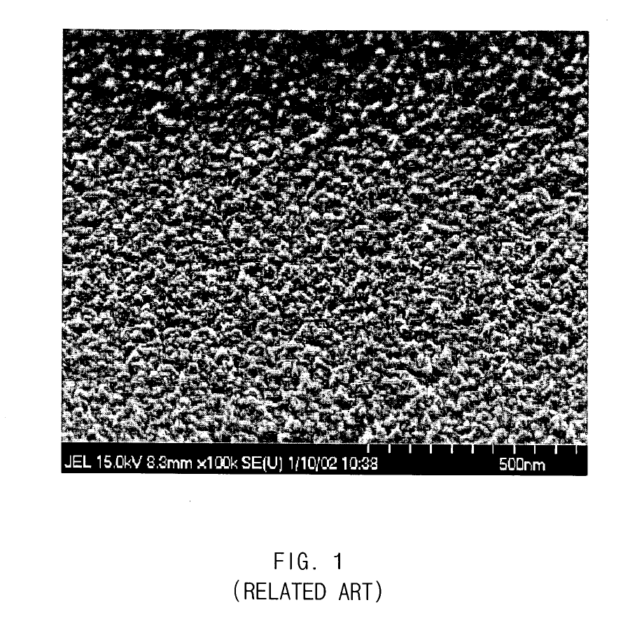

FIG. 2 is a scanning electron microscopic (SEM) photograph of a ruthenium film that is deposited on TiN film according to the related art;

FIG. 3 is a timing chart illustrating a period for a supply of source material and reaction gases;

FIG. 4 is a scanning electron microscopic (SEM) photograph of a ruthenium film that is deposited on TiN film according to the present invention; and

FIG. 5 is a scanning electron microscopic (SEM) photograph of a ruthenium film that is formed in a trench structure of a semiconductor device according to the present invention.

### DETAILED DESCRIPTION OF THE ILLUSTRATED EMBODIMENTS

Reference will now be made in detail to the illustrated embodiment of the present invention, which is illustrated in the accompanying drawings.

A forming sequence of a ruthenium (Ru) film as a capacitor electrode for a semiconductor device will be described hereinafter with reference to attached figures. The present invention uses SiO₂ film or TiN film as a barrier layer on a semiconductor substrate. The semiconductor substrate on which the barrier layer is formed is loaded into a reaction chamber that is a place where a deposition process is performed under a low pressure atmosphere and a temperature of the semiconductor substrate is kept at 260° C. Subsequently, Ru(OD)₃ is supplied into the reaction chamber as a ruthenium (Ru) source material and absorbed into the barrier layer. The reaction chamber is subsequently purged by a argon gas (Ar) and then oxygen gas (O₂) is supplied to the reaction chamber to form a ruthenium atomic layer by removing a ligand of Ru(OD)₃ that is absorbed into the barrier layer. The reaction chamber is purged again by argon gas (Ar). The above processes from a process for supplying the ruthenium source material to the reaction chamber to a process for supplying argon gas (Ar) to the chamber to purge the reaction chamber after the ruthenium atomic layer is formed are periodically repeated to form the ruthenium film in a certain thickness on the barrier layer.

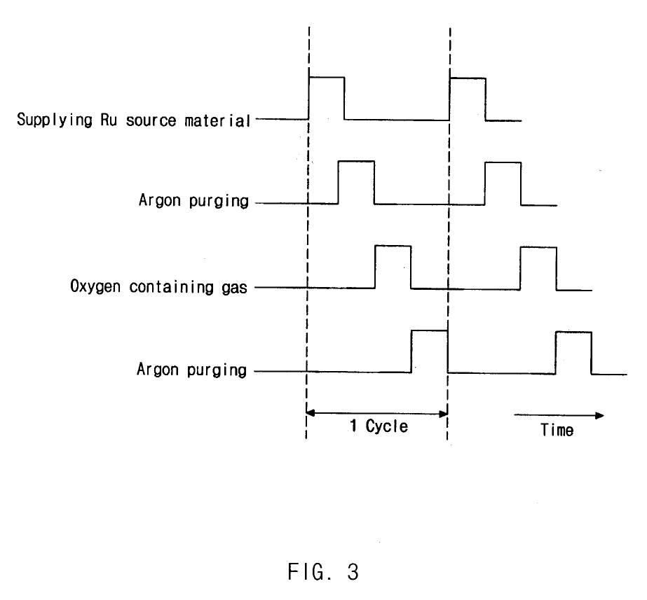

FIG. 3 is a timing chart illustrating a period for a supply of source material and reaction gases. In FIG. 3, each process for forming the ruthenium film is illustrated as a pulse. Each optimum time in a cycle for the supply of Ru(OD)3, the argon purging, the supply of the oxygen and then the argon purging is set to between 0.5 and 10 seconds in the present invention. Consequently, the ruthenium film having a thickness of 150˜300 is formed on SiO2 or TiN barrier layer by repeating the cycle for four hundred time. The thickness of the deposited ruthenium film in each cycle may be different from that of other cycle owing to an effect of the barrier layer. According to the above ruthenium deposition method, the ruthenium film can be deposited by a layer and a rapid change of properties of the deposited ruthenium film depending on the oxygen ratio can be minimized. In addition, the ruthenium film can be prevented from growing in a shape of island.

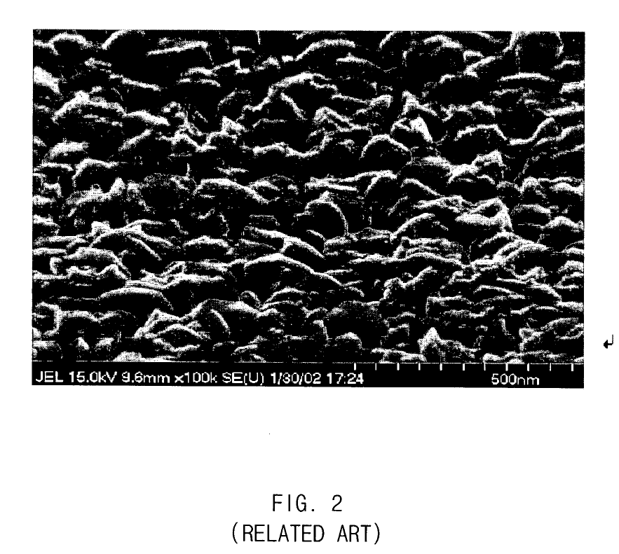

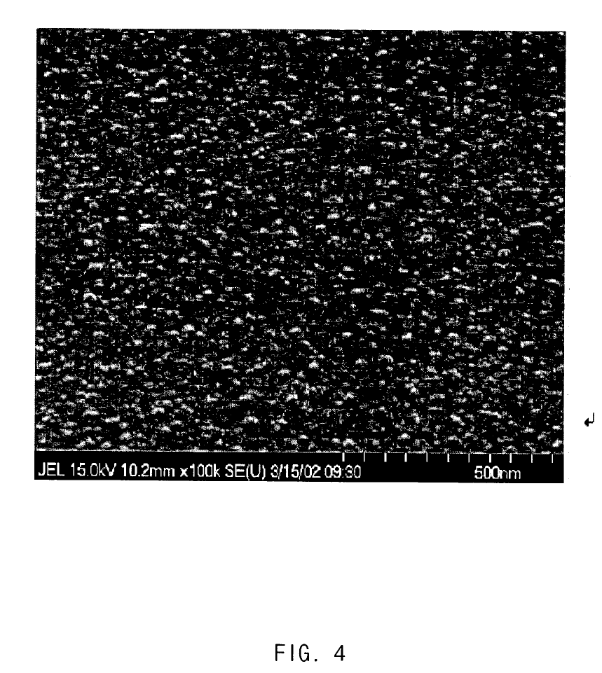

FIG. 4 is a scanning electron microscopic (SEM) photograph of the ruthenium film that is deposited on TiN film according to the present invention. If FIG. 4 is compared to FIG. 2, the surface roughness of the deposited ruthenium film is greatly improved when the present invention is used for forming the ruthenium film compared to the related art. A RMS (root mean square) value of the surface roughness of the ruthenium film that is formed on the TiN barrier layer by the present invention is about 20 and this value is much lower than that of the related art. That is, the RMS value of the ruthenium film that is formed on the TiN barrier layer by the related art is about 50 as stated in FIG. 2.

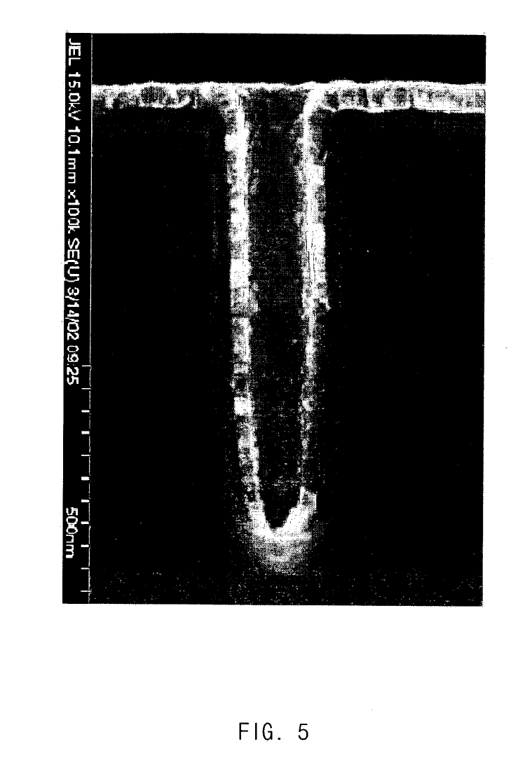

FIG. 5 is a scanning electron microscopic (SEM) photograph of a ruthenium film that is formed in a trench structure of a semiconductor device according to the present invention. That is, if the ruthenium film is deposited on the barrier layer that is formed on the trench structure of the semiconductor device, a step coverage is greatly improved. The specific resistance is also reduced to 70% of that of the related art. According to the conventional MOCVD (metal-organic chemical vapor deposition) method for depositing the ruthenium film under a best morphology condition, a deposition rate of the ruthenium film is about 80/min and the specific resistance is between 50 and 70 μΩ-cm when a thickness of the deposited ruthenium film is 500. The best morphology condition means that the surface of the deposited ruthenium film can be formed most smooth. If the ruthenium film is deposited according to the conventional MOCVD method under a best step coverage condition, the deposition rate is about 30/min and the specific resistance is between 100 and 150 μΩ-cm when the thickness of the deposited ruthenium film is 500. On the other hand, the deposition rate of the ruthenium film is 0.7/cycle and the specific resistance of the deposited ruthenium film is between 15 and 26 μΩ-cm when the thickness of the deposited ruthenium film is 300. Because an atomic radius of the ruthenium (Ru) is 1.89 the thickness of the deposited ruthenium film per cycle is expected to be equal or under the atomic radius of the ruthenium (Ru). Accordingly, the deposition rate of the ruthenium film is 0.7/cycle in the present invention and which results from a self-limited deposition in which the deposition is performed for a relatively short time in each cycle compared to the conventional CVD (chemical vapor deposition) method in which source material and reaction gas are supplied into the reaction chamber at a time. The specific resistance of the metal including ruthenium (Ru) that has a thickness under a critical value tends to be very high. However, the specific resistance of the ruthenium film that is deposited according to the present invention is relatively low even when the thickness of the deposited ruthenium film is under 200 and this low specific resistance is acquired owing to a continuous deposition of the ruthenium film.

In the present invention, the ruthenium film is deposited in a way that a physical absorption is carried out in a process for the source material supply and then a chemical absorption is carried out by removing the ligand using the oxygen gas in a process for the oxygen gas supply. Accordingly, as stated above the present invention can provide a ruthenium film that has a greatly improved step coverage and a morphology according to the present invention. That is, properties of the ruthenium film such as the surface roughness, the specific resistance and the step coverage can be greatly improved. In addition, an effect of a semiconductor substrate to the deposited ruthenium film can be minimized and impurities contained in the deposited ruthenium film can be effectively removed from the ruthenium film. Accordingly, it is easy to secure a reproducibility of the ruthenium film and a credibility of the semiconductor devices can be greatly improved.

It will be apparent to those skilled in the art that various modifications and variation can be made in the fabrication and application of the present invention without departing from the spirit or scope of the invention. Thus, it is intended that the present invention cover the modifications and variations of this invention provided they come within the scope of the appended claims and their equivalents.

What is claimed is:

1. A method for forming ruthenium film of a semiconductor device, comprising:
(a) forming a barrier layer on a semiconductor substrate;
(b) loading the semiconductor substrate on which the barrier layer is formed into a reaction chamber;
(c) supplying Ru(OD)₃ into the reaction chamber to be absorbed onto the barrier layer;
(d) purging the reaction chamber by supplying argon gas into the reaction chamber;
(e) supplying reaction gas containing oxygen into the reaction chamber and forming a ruthenium atomic layer by removing a ligand of RU(OD)₃ on the barrier layer using the oxygen gas;
(f) purging the reaction chamber by supplying argon gas into the reaction chamber again; and
(g) forming a ruthenium film having a certain thickness on the barrier layer by repeating steps from the step (c) and to the step (f) while the semiconductor substrate is kept at a temperature of 200˜350° C.

2. The method according to claim 1, wherein the barrier layer is formed one of SiO2 and TiN and the ruthenium film serves as a lower electrode of a capacitor for the semiconductor device.

3. The method according to claim 1, wherein the barrier layer is formed one of high dielectric substance such as Ta₂O₅ and BST and the ruthenium film serves as an upper electrode of a capacitor for the semiconductor device.

4. The method according to claim 1, wherein the reaction gas containing oxygen is one of oxygen gas and Na₂O.
